(19) United States
(12) Patent Application Publication
(10) Pub. No.: US 2016/0072047 A1
(43) Pub. Date: Mar. 10, 2016

(54) SEMICONDUCTOR MEMORY DEVICE AND MANUFACTURING METHOD THEREOF

(71) Applicants: Satoshi SETO, Seoul (KR); Masatoshi YOSHIKAWA, Seoul (KR); Shuichi TSUBATA, Seoul (KR); Kazuhiro TOMIOKA, Seoul (KR)

(72) Inventors: Satoshi SETO, Seoul (KR); Masatoshi YOSHIKAWA, Seoul (KR); Shuichi TSUBATA, Seoul (KR); Kazuhiro TOMIOKA, Seoul (KR)

(21) Appl. No.: 14/629,087

(22) Filed: Feb. 23, 2015

Related U.S. Application Data
(60) Provisional application No. 62/047,584, filed on Sep. 8, 2014.

(51) Int. Cl. H01L 43/08; H01L 43/12; H01L 43/02

(52) U.S. Cl. CPC H01L 43/08; H01L 43/02; H01L 43/12

(57) ABSTRACT

According to one embodiment, a semiconductor memory device includes a lower electrode, an MTJ element, a cap layer and an upper electrode. The lower electrode is provided above a semiconductor substrate. The MTJ element is provided above the lower electrode. The cap layer is provided above the MTJ element and is oxygen-free. The upper electrode is connected to the cap layer.

### CROSS-REFERENCE TO RELATED APPLICATIONS

This application claims the benefit of U.S. Provisional Application No. 62/047,584, filed Sep. 8, 2014, the entire contents of which are incorporated herein by reference.

### FIELD

Embodiments described herein relate generally to a semiconductor memory device applied to, for example, a magnetoresistive random access memory (MRAM), and a method of manufacturing the same.

### BACKGROUND

MRAM is a generic term for a nonvolatile semiconductor memory which utilizes that the resistance of a barrier layer varies by the magnetization direction of a ferromagnetic material. A memory cell of an MRAM comprises a magnetic tunnel junction (MTJ) which utilizes the tunneling magnetoresistive (TMR) effect and a transistor. The MTJ element is a three-layered thin film comprising a recording layer and a reference layer, which are formed of magnetic materials, and an insulating layer interposed therebetween. The MTJ element stores data based on the magnetization states of the recording layer and reference layer.

In order to achieve a large capacity by miniaturizing the cell size and also a low current, a spin injection MRAM which employs a spin transfer torque (STT) write mode has been proposed. In the spin injection MRAM, data is written to the MTJ element when a current flows in a vertical direction with respect to a film surface of the MTJ element. As the magnetic layer used for the MTJ element, a vertical magnetization film in which the magnetization direction is set in, for example, the vertical direction with respect to the film surface has been proposed.

The MTJ element is processed by the following procedure. That is, magnetic layers and insulating layers are stacked one on another. Then, a hard mask is formed, and the magnetic layers and insulating layers are processed by ion beam etching (IBE) using the hard mask all at once. IBE is physical sputtering using an ion beam. By this means, it is difficult to process a high-density MTJ element due to the shadowing effect. As a masking material for processing an MTJ element, diamond-like carbon (DLC), which has a high selection ratio in physical sputtering, has been receiving attention.

### BRIEF DESCRIPTION OF THE DRAWINGS

FIG. 1 is a cross-sectional view showing an example of a semiconductor memory device according to a first embodiment;

FIG. 2 is a cross-sectional view illustrating a method of manufacturing a semiconductor memory device according to the first embodiment;

FIG. 3 is a cross-sectional view showing a manufacturing process subsequent to FIG. 2;

FIG. 4 is a cross-sectional view showing a manufacturing process subsequent to FIG. 3;

FIG. 5 is a cross-sectional view showing a manufacturing process subsequent to FIG. 4;

FIG. 6 is a cross-sectional view showing a manufacturing process subsequent to FIG. 5;

FIG. 7 is a cross-sectional view showing a manufacturing process subsequent to FIG. 6;

FIG. 8 is a cross-sectional view showing a manufacturing process subsequent to FIG. 7;

FIG. 9 is a cross-sectional view showing a manufacturing process subsequent to FIG. 8;

FIG. 10 is a cross-sectional view showing a manufacturing process subsequent to FIG. 9;

FIG. 11 is a cross-sectional view showing a manufacturing process subsequent to FIG. 10;

FIG. 12 is a cross-sectional view showing a manufacturing process subsequent to FIG. 11;

FIG. 13 is a cross-sectional view showing a manufacturing process subsequent to FIG. 12;

FIG. 14 is a cross-sectional view showing a semiconductor memory device according to a second embodiment, together with an initial stage of a method of manufacturing the same; and

FIG. 15 is a cross-sectional view showing a semiconductor memory device according to the second embodiment, together with a stage later than that shown in FIG. 14.

### DETAILED DESCRIPTION

In general, according to one embodiment, a semiconductor memory device comprises a lower electrode, an MTJ element, a cap layer and an upper electrode. The lower electrode is provided above a semiconductor substrate. The MTJ element is provided above lower electrode. The cap layer is provided above the MTJ element and does not contain oxygen. The upper electrode is connected to the cap layer.

Embodiments will now be described with reference to the drawings. Throughout the drawings, the same parts are designated by the same reference numbers.

### First Embodiment

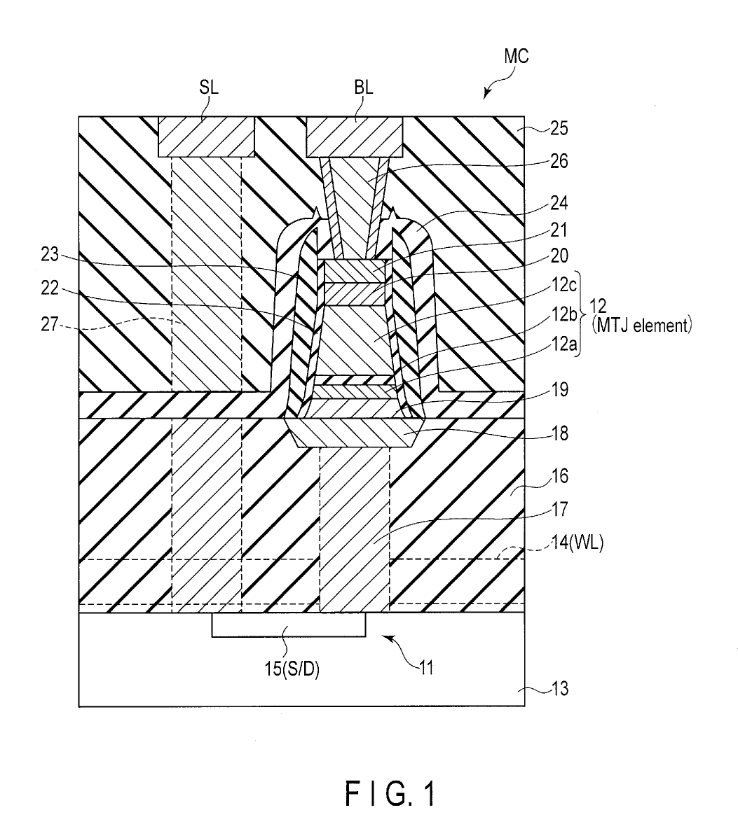

FIG. 1 schematically shows a semiconductor device according to the first embodiment, that is, for example, a memory cell MC of MRAM. The memory cell MC comprises, for example, one transistor 11 and one MTJ element 12. For example, in a silicon substrate 13, a shallow trench isolation (STI) region (not shown) serving as an element separation region is formed. On the substrate 13, a gate electrode 14 of the transistor 11 is formed via a gate insulating film (not shown). The gate electrode 14 is connected to a gate electrode of an adjacent memory cell (not shown) located in a row direction, and thus forms a word line WL. In the substrate 13 located on both sides of the gate electrode 14, diffusion layers 15 which constitute source/drain (S/D) regions are formed.

On the substrate 13, an interlayer insulating film 16 which covers the transistor 11 is formed, and in the interlayer insulating film 16, a lower contact plug 17 serving as a contact layer and electrically connected to one side of the diffusion layers 15 constituting the S/D regions is formed. A lower electrode 18 is formed on the lower contact plug 17. The lower electrode 18 is formed of, for example, tantalum (Ta). For example, a lower layer 19 is formed on the lower electrode 18. The lower layer 19 is formed of, for example, a hafnium boride (HfB). But, it is not limited to HfB, but also, aluminum nitride (AlN) can be used. The MTJ element 12 is formed on the lower layer 19.

The MTJ element 12 comprises, for example, a magnetic layer 12a, a barrier layer 12b as an insulating layer, and a magnetic layer 12c. The magnetic layers 12a and 12c are formed of, for example, CoFeB, whereas the barrier layer 12c is formed of, for example, MgO. Of the magnetic layer 12a and 12c, one whose magnetization direction is fixed is called a fixed layer (reference layer), and one whose magnetization direction is reversed by STT is called a free layer (storage layer). In this embodiment, the magnetic layer 12a is, for example, a fixed layer, and the magnetic layer 12c is, for example, a free layer.

In this embodiment, the MTJ element 12 is not limited to the above-described structure, but it may be modified into various versions. For example, the element may have such a structure that the fixed layer further comprises an interference layer in contact with the barrier layer, or the fixed layer comprises the first magnetic layer, ruthenium (Ru) and the second magnetic layer. Further, the MTJ element 12 may have such a structure that comprises a first fixed layer, a first barrier layer, a free layer, a second barrier layer and a second fixed layer.

An upper layer 20 is formed on the MTJ element 12. The upper layer 20 is formed of, for example, ruthenium (Ru). Note that it is not limited Ru, but also, for example, tungsten (W) or titanium nitride (TiN) can be applied. A cap layer 21 is formed on the upper layer 20. The cap layer 21 serves to prevent degradation of DLC used as a hard mask when processing the material of the MTJ element 12 by IBE, and also oxidation of the MTJ element 12 when removing DLC. For this reason, the cap layer 12 comprises a material free of oxygen. However, it can be considered that in a manufacturing process, slight oxygen is mixed in the cap layer 12 unintentionally. Such the cap layer 12 including the slight oxygen is also defined as comprising the material free of oxygen.

That is, the cap layer 21 is formed of, for example, one of Ta, tungsten (W), titanium (Ti) and silicon (Si), or one of carbides of Ta, W, Ti and Si, or one of nitrides of Ta, W, Ti and Si. Further, the cap layer 21 may have a multi-layer structure comprising one of Ta, W, Ti and Si and a carbide thereof, or one of Ta, W, Ti and Si and a nitride thereof.

On sidewalls of the MTJ element 12, the upper layer 20 and the cap layer 21, slight oxide films 22 are formed. The oxide films 22 comprise oxides of the material of the MTJ element, which is re-deposited when etching the material of the MTJ element 12. With the oxide films 22, a shunt error of the sidewalls of the MTJ element 12 can be prevented.

On each of the oxide films 22, a side-wall insulating film 23 comprising, for example, silicon nitride, is formed. On the silicon nitride film 23, a protective film 24 comprising, for example, silicon nitride, is formed. An insulating film 25 is formed on the protective film 24. An upper electrode 26 is formed in parts of the insulating film 25 and the protective film 24 and is connected to the cap layer 21. A bit line BL is formed on the upper electrode 26. The bit line BL is placed in a direction orthogonal to the word line WL.

Meanwhile, a contact 27 is formed in the interlayer insulating film 16 corresponding to the other side of the diffusion layer 15 constituting the S/D regions, the protective film 24 and the insulating film 25. The contact 27 is electrically connected to the other side of the diffusion layer 15 constituting the S/D regions. A source line SL is formed on the contact 27 is arranged along the bit line BL.

### Manufacturing Method

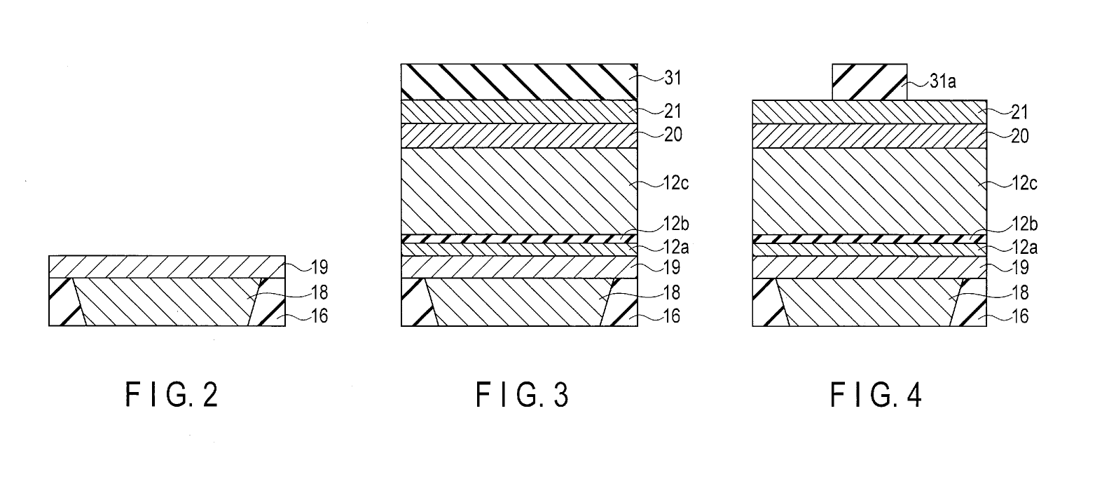

FIGS. 2 to 13 briefly illustrate manufacturing steps of the MTJ element 12 of MRAM according to the first embodiment. In the FIGS. 2 to 13, the manufacturing process of the transistor and the like, which are formed before the MTJ element 12, is omitted.

As shown in FIG. 2, the lower electrode 18 is formed inside the interlayer insulating film 16, and then the lower electrode 19 of, for example, HfB, is formed on the lower electrode 18 and the interlayer insulating film 16.

Next, as shown in FIG. 3, the materials of the magnetic layer 12a, the barrier layer 12b and the magnetic layer 12c are formed in the order on the lower electrode 19. More specifically, for example, an MgO layer as the barrier layer 12b is formed on, for example, a CoFeB layer as the magnetic layer 12a, and for example, a CoFeB layer as the magnetic layer 12c is formed on the MgO layer. Further, for example, a ruthenium layer as the upper layer 20 is formed on the magnetic layer 12c, and the cap layer 21 is formed on the upper layer 20.

The cap layer 21, as mentioned above, comprises a material free of oxygen, which is one of Ta, W, Ti and Si, or a carbide or nitride of one of Ta, W, Ti and Si. The carbide or nitride material is an extremely thin layer of a thickness of, for example, 2 to 3 nm. Further, the cap layer 21 may be of a multi-layer structure comprising, for example, one of Ta, W, Ti and Si and a carbide of one of Ta, W, Ti and Si, or one of Ta, W, Ti and Si and a nitride of one of Ta, W, Ti and Si.

In order to increase the adhesive force between the cap layer 21 and a DLC film 31 to be formed thereon, and also to prevent the oxidization of the MTJ element 12 when removing the hard mask comprising the DLC film 31, the surface of the DLC film 31 should preferably be slightly nitrided.

After that, the DLC film 31 serving as the mask material is formed on the cap layer 21. The DLC film 31 is formed of amorphous carbon comprising carbon containing, for example, both sp3 bond of diamond and sp2 bond of graphite. The DLC film 31 has a hardness of 80 GPa or less. The DLC film 31 is formed by, for example, a physical vapor deposition (PVD) method or a chemical vapor deposition (CVD) method. As to the PVD, sputtering, ion beam deposition, cathodic arc ion plating, laser ablation or the like is carried out using a solid raw material, such as graphite, to form a DLC film. The DLC film formed by PVD contains a very smaller amount of hydrogen as compared to that of the CVD, and in fact, does not substantially contain hydrogen. In the meantime, as to the CVD method, plasma-enhanced CVD which uses a gaseous material containing carbon, for example, C₂H₂, may be used to form a DLC film. The DLC film formed by CVD contains hydrogen.

After that, as shown in FIG. 4, the DLC film 31 is patterned into a DLC mask 31a.

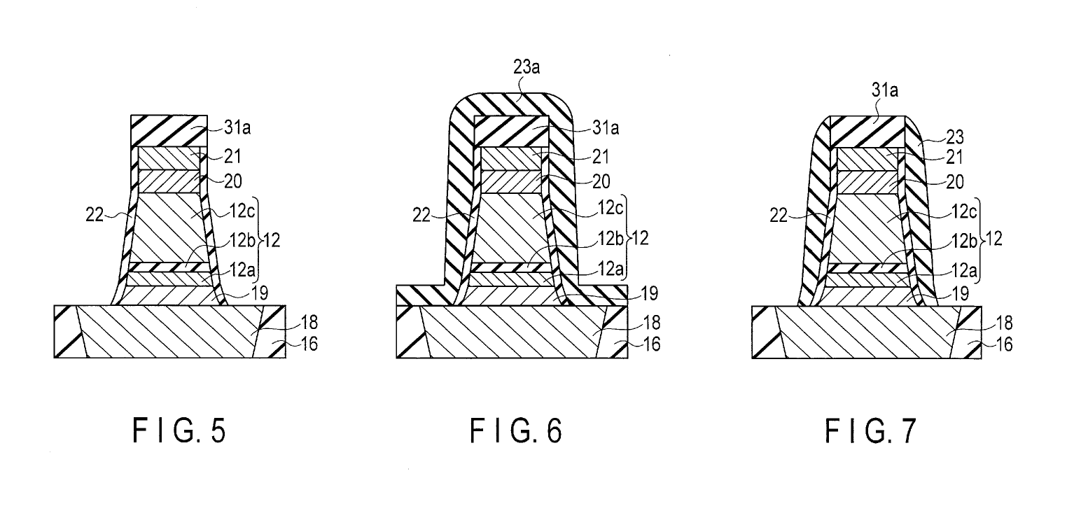

Next, as shown in FIG. 5, with the DLC mask 31a as a mask, the cap layer 21, the upper layer 20, the magnetic layer 12a, the barrier layer 12b, the magnetic layer 12c and the lower layer 19 are etched altogether by IBE, and thus the MTJ element 12 is formed. The IBE is physical etching by sputtering using, for example, argon (Ar) ions, and during the etching, metal elements scattering from the magnetic layers 12a and 12c, the barrier layer 12b and the like redeposit on sidewalls of the MTJ element 12 including the lower layer 19, the upper layer 20 and the cap layer 21. The deposit re-deposited on the sidewalls of the MTJ element 12 is such a slight amount that the deposit does not crystallize.

After that, for example, water vapor (H₂O) is introduced into the chamber in which the IBE was carried out, and the deposit re-deposited on the sidewalls of the MTJ element 12 and the sidewalls of the MTJ element 12 are oxidized. That is, the process by IBE and the in-situ oxidization process by H₂O are carried out continuously. The oxidation process is carried out by exposing a wafer to H₂O at room temperature, for example, and for 2 to 3 minutes, for example. With this oxidization process, the sidewalls of the MTJ element 12 are oxidized, and thus passivated. In other words, an oxide film 22 is formed on the sidewalls of the MTJ element 12 including the lower layer 19, the upper layer 20 and the cap layer 21, and is prevented from a shunt error.

Next, as shown in FIG. 6, a silicon nitride film 23a, for example, is formed on an entire surface of the MTJ element 12 so as to cover the MTJ element 12. Then, as shown in FIG. 7, the silicon nitride film 23a is etched back, and thus the insulating film 23 is formed on the sidewalls of the MTJ element 12.

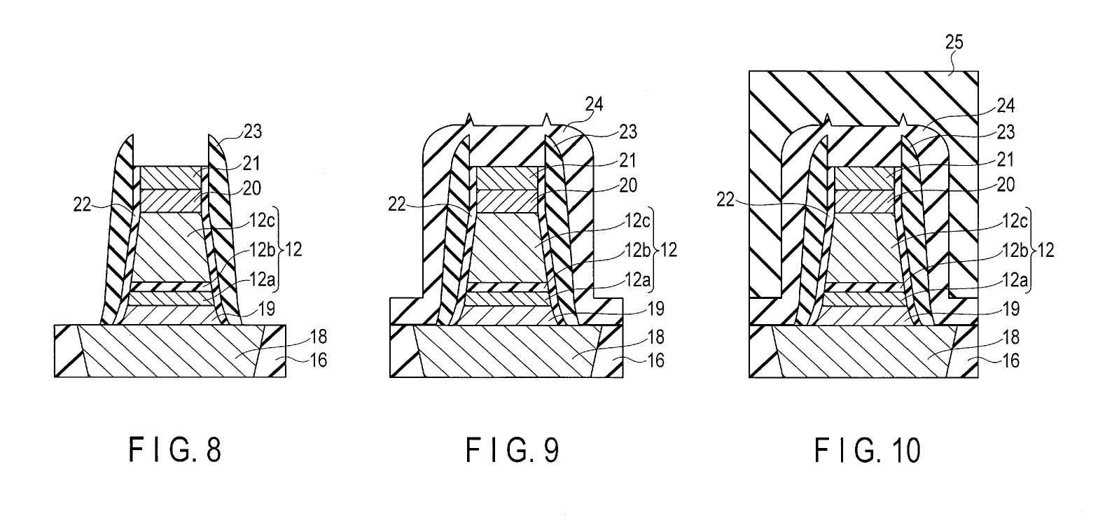

Next, as shown in FIG. 8, the DLC mask 23 is asked using oxygen plasma or oxygen radicals so as to be removed. When the DLC mask 23 is removed, the surface of the cap layer 21 is oxidized.

After that, as shown in FIG. 9, the protective film 24 comprising, for example, silicon nitride is deposited on the entire surface of the resultant structure. Subsequently, as shown in FIG. 10, an interlayer insulating film 25 comprising, for example, silicon oxide, is deposited thereon by means of high-density plasma (HDP).

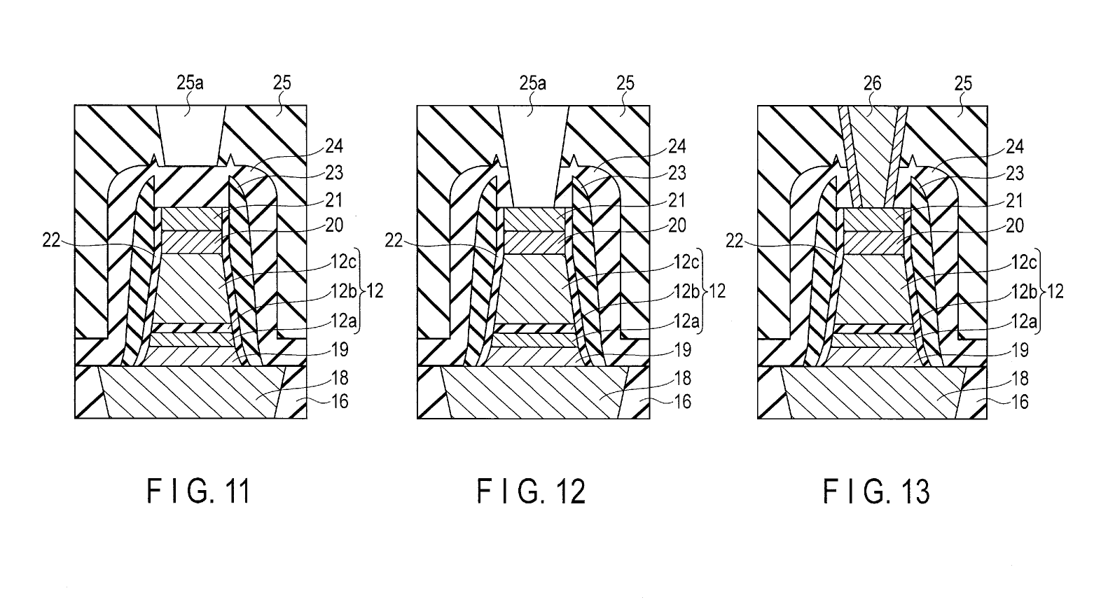

Next, as shown in FIG. 11, with a resist mask (not shown), an opening 25a is formed in the interlayer insulating film 25 to expose the silicon nitride film 24 by, for example, reactive ion etching (RIE).

Next, as shown in FIG. 12, the silicon nitride film 24 exposed in the opening 25a is etched by RIE, and thus the surface of the cap layer 21 is exposed.

After that, as shown in FIG. 13, the inside of the opening 25a is pretreated using H₂SO₄ or H₂O₂, for example, as an etchant, and thus the oxide film formed on the surface of the cap layer 21 is removed. Next, the upper electrode 26 to be electrically connected to the cap layer 21 is formed in the opening 25a. The upper electrode 26 has a laminated structure of titanium nitride (TiN) and tungsten (W) as an underlying layer. That is, TiN and W are deposited in lamination on the entire surface, and the lamination of these is planarized by chemical mechanical etching (CMP) using the interlayer insulating film 25 as a stopper. Thus, the upper electrode 26 is formed.

After that, as shown in FIG. 1, the contact 27, the bit line BL and the source line SL are formed, and thus the memory cell MC of MRAM is completed.

According to the first embodiment, the cap layer 21 formed underneath the DLC mask 31a comprises an oxygen-free material. With this structure, it is possible to prevent the generation of oxygen radicals from the cap layer 21 during the processing of the material of the MTJ element 12 using the DLC mask 31a as a mask by IBE, thereby making it possible to reduce the damage of the DLC mask 31a. Thus, the shape of the DLC mask 31a can be stably maintained, and therefore the MTJ element 12 having a fine structure can be processed with high accuracy.

Further, the cap layer 21 can prevent the oxidization of the MTJ element 12 when the DLC mask 31a is ashed by oxygen plasma or oxygen radicals so as to be removed. Therefore, it is possible to prevent the degradation of the magnetic characteristics of the MTJ element 12.

In addition, when the cap layer 21 comprises a carbide of one of Ta, W, Ti and Si, or a nitride of one of Ta, W, Ti and Si, the oxidization of the surface of the cap layer 21, which may occur when the DLC mask 31a is removed, can be prevented. Therefore, here, it is not required to subject the inside of the opening 25a to a reduction process when forming the upper electrode 26, and thus the manufacturing process can be simplified.

### Second Embodiment

In the first embodiment, the DLC mask 31a is formed directly on the cap layer 21. In contrast, according to the second embodiment, an anti-oxidization layer is provided between a cap layer 21 and a DLC mask 31a.

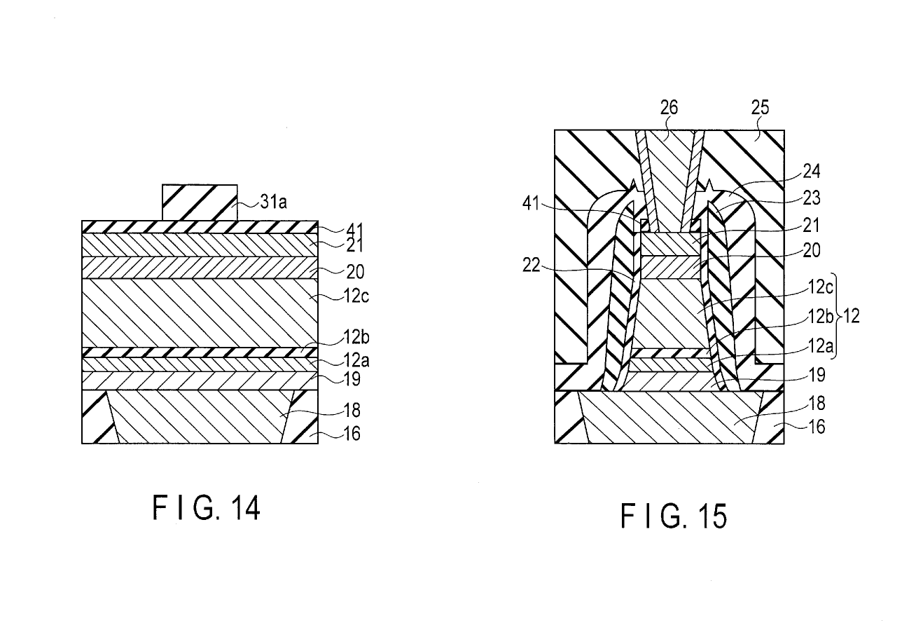

That is, as shown in FIG. 14, an anti-oxidization layer 41 is formed on the cap layer 21. When the cap layer 21 is formed of one of Ta, W, Ti and Si, or a carbide of one of Ta, W, Ti and Si, the anti-oxidization layer 41 comprises a nitride of the material of the cap layer 21. That is, when the cap layer 21 consists of Ta, the anti-oxidization layer 41 comprises TaN. Or when the cap layer 21 comprises SiC, for example, the anti-oxidization layer 41 comprises SiCN. Note that the anti-oxidization layer 41 may comprise a nitride of some material other than that of the cap layer 21. For example, when the cap layer 21 comprises Ta, the anti-oxidization layer 41 may comprise TiN.

The DLC mask 31a is formed on the anti-oxidization layer 41. Using the DLC mask 31a, the anti-oxidization layer 41, a cap layer 21, an upper layer 20, a magnetic layer 12c, a barrier layer 12b, a magnetic layer 12a and a lower layer 19 are etched by IBE. The manufacturing process from this step on is the same as that of the first embodiment, and therefore the explanation thereof will be omitted.

Note that the anti-oxidization layer 41 remains even after the removal of the DLC mask 31a, and as shown in FIG. 15, the upper layer 26 to be connected to the cap layer 21 is formed in an insulating film 25, a protecting film 24 and the anti-oxidization layer 41.

According to the second embodiment, the anti-oxidization layer 41 and the cap layer 21 each comprise an oxygen-free material. With this structure, it is possible to prevent generation of oxygen radicals from the anti-oxidization layer 41 and the cap layer 21 during the processing of the material of the MTJ element 12 using the DLC mask 31a as a mask by IBE. In this manner, it is possible to prevent the damage of the DLC mask 31a, and therefore the MTJ element 12 having a fine structure can be processed with high accuracy.

Further, the oxidization of the cap 21 and the MTJ element 12 can be prevented by the anti-oxidization layer 41 when the DLC mask 31a is ashed by oxygen plasma or oxygen radicals. Therefore, it is possible to prevent the degradation of the magnetic characteristics of the MTJ element 12.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a lower electrode above a semiconductor substrate;
a magnetic tunnel junction (MTJ) element above the lower electrode;
an oxygen-free cap layer above the MTJ element; and
an upper electrode connected to the cap layer.

2. The device according to claim 1, wherein the cap layer is one of tantalum (Ta), tungsten (W), titanium (Ti) and silicon (Si).

3. The device according to claim 1, wherein the cap layer is a nitride of one of Ta, W, Ti and Si.

4. The device according to claim 1, wherein the cap layer is a laminated layer of one of Ta, W, Ti and Si and a nitride thereof.

5. The device according to claim 1, wherein the cap layer is a carbide of one of Ta, W, Ti and Si.

6. The device according to claim 1, wherein the cap layer is a laminated layer of one of Ta, W, Ti and Si and a carbide thereof.

7. A method of manufacturing a semiconductor memory device, comprising:
forming a lower electrode above a semiconductor substrate;
forming a first magnetic layer and a second magnetic layer above the lower electrode, and an insulating layer therebetween;
forming an oxygen-free cap layer above the second magnetic layer;
forming a mask layer containing diamond-like carbon (DLC) above the cap layer;
etching the cap layer, the second magnetic layer, the insulating layer and the first magnetic layer using the mask layer as a mask, thereby forming a magnetic tunnel junction (MTJ) element;
removing the mask layer; and
forming an upper electrode to be connected to the cap layer.

8. The method according to claim 7, wherein the cap layer is one of tantalum (Ta), tungsten (W), titanium (Ti) and silicon (Si).

9. The method according to claim 8, wherein the cap layer is a nitride of one of Ta, W, Ti and Si.

10. The method according to claim 8, wherein the cap layer is a laminated layer of one of Ta, W, Ti and Si and a nitride thereof.

11. The method according to claim 8, wherein the cap layer is a carbide of one of Ta, W, Ti and Si.

12. The method according to claim 8, wherein the cap layer is a laminated layer of one of Ta, W, Ti and Si and a carbide thereof.

13. The method according to claim 7, wherein the MTJ element is formed by ion beam etching (IBE) using the mask layer as a mask.

14. The method according to claim 12, further comprising forming an anti-oxidization layer on the cap layer before forming the mask layer.

15. The method according to claim 14, wherein the anti-oxidization layer is a nitride of a material of the cap layer.

16. The method according to claim 7, wherein the mask layer is removed by ashing using oxygen.

17. The method according to claim 14, wherein the anti-oxidization layer is a nitride of a material different from that of the cap layer.
